(19) United States
(12) Patent Application Publication
(10) Pub. No.: US 2006/0232204 A1
(43) Pub. Date: Oct. 19, 2006

(54) Double-sided electroluminescene display

(75) Inventor: Min-Chieh Hu, Shanhua Town (TW)

Correspondence Address: GENUS LAW GROUP, 5543 TALON COURT, FAIRFAX, VA, 22032, US

(73) Assignee: AU Optronics Corporation

(21) Appl. No.: 11/155,255

(22) Filed: Jun. 17, 2005

(30) Foreign Application Priority Data
Apr. 15, 2005 (TW) 94112018

(51) Int. Cl. H01L 51/00

(52) U.S. Cl. 313/519; 313/504

(57) ABSTRACT

A double-sided electroluminescene display, comprising two electroluminescene substrates, is provided. Within the double-sided electroluminescene display, the bonding areas of two electroluminescene substrates are arranged in the different sides of the double-sided electroluminescene display, so as to connect with respective circuit circuits.

This application claims the benefit of Taiwan application Serial No. 94112018, filed Apr. 15, 2005, the subject matter of which is incorporated herein by reference.

### FIELD OF THE INVENTION

The present invention relates to a double-sided display, and more particularly relates to a double-sided electroluminescene display.

### DESCRIPTION OF THE RELATED ART

In a display device, to provide a double-sided display with different angles is an important issue. The common clamshell cell phone with the design of the double-sided display is a typical example. Referring to FIG. 1, a cross-sectional view of a conventional double-sided display utilizing organic light emitting diodes (OLEDs) is shown. The double-sided organic light emitting diode display 1 comprises a first organic light emitting diode substrate 11 and a second organic light emitting diode substrate 12 disposed back-to-back to form a double-sided panel structure. There is a sealant 13 disposed between first organic light emitting diode substrate 11 and second organic light emitting diode substrate 12 for sealing. In the double-sided organic light emitting diode display 1, the first organic light emitting diode substrate 11 comprises a first substrate 111 and first organic light emitting diodes 112, and the second organic light emitting diode substrate 12 comprises a second substrate 121 and second organic light emitting diodes 122. A protective layer 14 and an absorbent 15 are sequentially formed on the surfaces of the first organic light emitting diodes 112 and the second organic light emitting diodes 122.

Still referring to FIG. 1, in the double-sided organic light emitting diode display 1 of the related art, a portion of the first substrate 111 and a portion of the second substrate 121 respectively protrude in the same side to form a first conductive circuit bonding area 111A and a second conductive circuit bonding area 121A arranged face-to-face respectively. Conductive circuits 111B and 121B are formed on the first conductive circuit bonding area 111A and the second conductive circuit bonding area 121A and electrically connect with the first organic light emitting diodes 112 and the second organic light emitting diodes 122 respectively, so as to electrically connect with a conductive circuit 16A disposed on the first circuit board 16 and a conductive circuit 17A disposed on the second circuit board 17 respectively and to transmit driving signals to the first OLEDs 112 and the second OLEDs 122.

However, the process of bonding the first circuit board 16 and the first conductive circuit bonding area 111A is always interfered because the second conductive circuit bonding area 121A and the first conductive circuit bonding area 111A are disposed in the same side of the double-sided lighting OLED display 1. Therefore, it is necessary to use specific equipment or a more complicated processing method to stably bond the first circuit board 16 to the first conductive circuit bonding area 111A. Similarly, the bonding process for the second circuit board 17 and the second conductive circuit bonding area 121A is also interfered by the first circuit board 16 and the first conductive circuit bonding area 111A.

In order to successfully bond the first circuit board 16 and the second circuit board 17 to the first conductive circuit bonding area 111A and the second conductive circuit bonding area 121A in the same side of the double-sided lighting OLED display 1 respectively, the thickness of the first circuit board 16 and the second circuit board 17 are crucial issues to be considered in the bonding process and additional space between the first circuit board 16 and the second circuit board 17 is necessary to be reserved for bonding so that the total thickness 1T can not be reduced and the possibilities of penetration of more moisture and oxygen is increased in the double-sided OLED display 1 and thereby decrease the term of use.

### SUMMARY OF THE INVENTION

According to the description of the related art, the excess thickness of the double-sided electroluminescene display would result in the penetration of moisture and oxygen and thereby shorten the term of use. Therefore, a double-sided electroluminescene display is provided to reduce the total thickness of the double-sided electroluminescene display and enhance the compactness. Moreover, it is another object of the present invention to reduce the difficulty of the bonding process applied to bond the double-sided electroluminescene display and the circuit board.

According to the purposes described above, a double-sided electroluminescene display is provided in the present invention. The two conductive circuit bonding areas in the electroluminescene substrate are disposed on the different sides of the double-sided electroluminescene display, and they may be connected to different circuit boards respectively to reduce the total thickness of the double-sided electroluminescene display.

### BRIEF DESCRIPTION OF THE DRAWINGS

The accompany drawings incorporated in and forming a part of the specification illustrate several aspects of the present invention, and together with the description serve to explain the principles of the invention. In the drawings:

FIG. 1 is a drawing of cross-sectional of view illustrating the double-sided electroluminescene display of the related art;

FIG. 2A is a drawing of cross-sectional view illustrating a double-sided electroluminescene display of one preferred embodiment of the present invention;

FIG. 2B is a drawing of top view illustrating a double-sided electroluminescene display of another preferred embodiment of the present invention;

FIG. 2C is a drawing of top view illustrating a double-sided electroluminescene display of another preferred embodiment of the present invention; and

FIG. 2D is a drawing of cross-sectional view illustrating a double-sided electroluminescene display of still one preferred embodiment of the present invention.

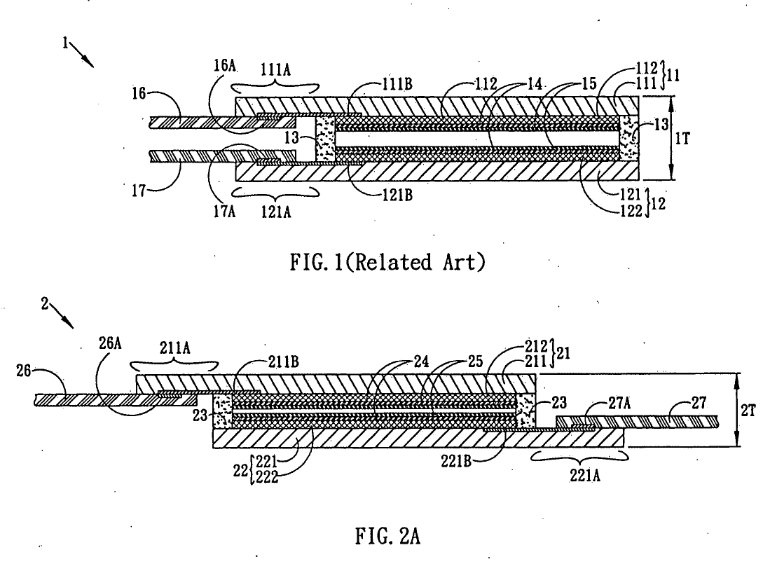

### DESCRIPTION OF THE PREFERRED EMBODIMENT

The following detailed description of the present invention describes a double-sided electroluminescene display necessary to provide an understanding of the present invention, but does not cover a complete structure composition and the operating theory. The portions relating to the conventional techniques are briefly described, and the parts of the drawings are not proportionally drafted. While embodiments are discussed, it is not intended to limit the scope of the present invention. Except expressly restricting the amount of the components, it is appreciated that the quantity of the disclosed components may be greater than that disclosed.

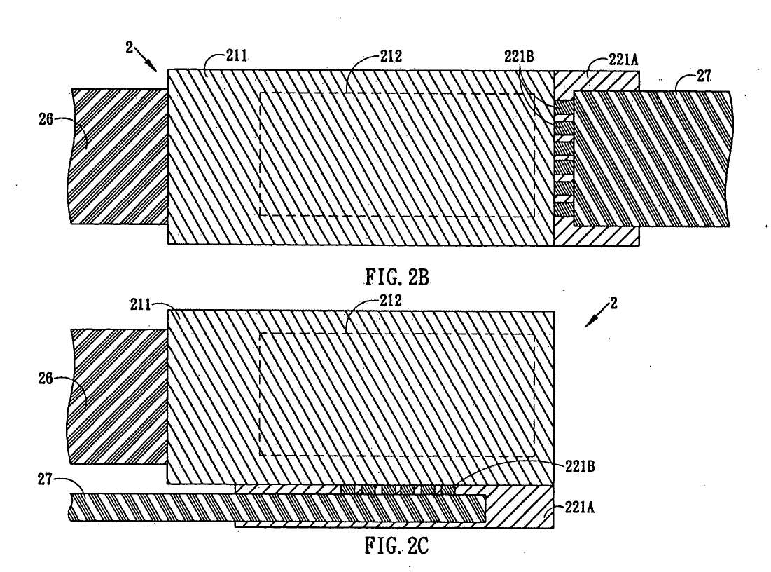

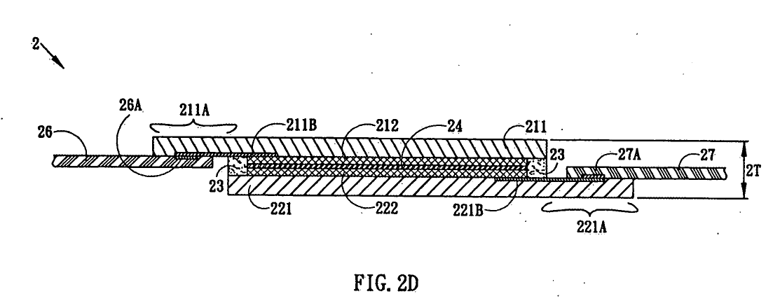

One of the preferred embodiments of the present invention discloses a double-sided electroluminescene display and FIG. 2A and FIG. 2B are the drawings of cross-sectional view and the top view thereof. First of all, referring to FIG. 2A, the double-sided electroluminescene display 2 provided in the present invention comprises a first electroluminescene substrate 21 and a second electroluminescene substrate 22 formed back to back to form a panel structure of double-sided output, and a sealant 23 surrounding and bonding the two electroluminescene substrates to achieve the compactness of the panel structure.

In the double-sided electroluminescene display 2 of the present invention, the first electroluminescene substrate 21 comprises a first substrate 211 and first electroluminescene light emitting diodes 212 disposed on the first substrate 211, and the second electroluminescene substrate 22 comprises a second substrate 221 and second electroluminescene light emitting diodes 222 disposed on the second substrate 221 so that both of them can be operated respectively or together to achieve the double-sided output. The first electroluminescene light emitting diodes 212 and the second electroluminescene light emitting diodes 222 comprises organic light emitting diodes or inorganic light emitting diodes. A protective layer 24 may be formed on the surfaces of the first electroluminescene light emitting diodes 212 and the second electroluminescene light emitting diodes 222 respectively or together for isolation or cushion. Besides, since the electroluminescene light emitting diode is easy to be damaged by moisture and oxygen, an absorbent 25 can be disposed respectively or together between the first electroluminescene light emitting diodes 212 and the second light emitting diodes 222 to maintain the normal operation of the double-sided electroluminescene display 2. The absorbent 25 can be a block or a layer structure, and any absorbent device or element, which can absorb moisture and treat the electroluminescene light emitting diode in a proper humidity condition, is in the scope of the present invention.

Still referring to FIG. 2A, in the double-sided electroluminescene display 2 of the present invention, a malpositional stack design can be applied between the first electroluminescene substrate 21 and the second electroluminescene substrate 22 to render portions of the first substrate 211 and the second substrate 221 protruding out from different sides or edges of the double-sided electroluminescene display 2 respectively to form a first conductive circuit bonding area 211A and a second conductive circuit bonding area 221A. A conductive circuit 211B is disposed in the first conductive circuit bonding area 211A and electrically connects to the first electroluminescene light emitting diodes 212 and a conductive circuit 221B is disposed on the second conductive circuit bonding area 221A and electrically connects to the second electroluminescene light emitting diodes 222. Therefore, the conductive circuits 211B and 221B can electrically connect with a conductive circuit 26A on a first circuit 26 board and a conductive circuit 27A on a second circuit board 27 respectively to transmit driving signals to the first electroluminescene light emitting diodes 212 and the second electroluminescene light emitting diodes 222.

Still referring to FIG. 2A, in the double-sided electroluminescene display 2 of the present invention, since the first conductive circuit bonding area 211A and the second conductive circuit bonding area 221A are disposed on the different sides of the double-sided electroluminescene display 2, so that the first conductive circuit bonding area 211A and the second conductive circuit bonding area 221A can be connected to the first circuit board 26 and the second circuit board 27 respectively without limitation and interference of the working space of the related art. Another advantage of this design is to reduce the thickness 2T of the double-sided electroluminescene display 2, and a sealant 23 is used to bond the first electroluminescene substrate 21 and the second electroluminescene 22 together to form a sealed double-sided electroluminescene display 2 and reduce the opportunity of the penetration of moisture and air.

Referring to FIG. 2A, in this embodiment, the first conductive circuit bonding area 211A and the first circuit board 26 and the second conductive circuit bonding area 221A and the second circuit board 27 are bonded by a compressing method. Other methods used to bond conventional circuit boards can also be used in the present invention.

In the double-sided electroluminescene display of the invention, the top view of the first electroluminescene substrate and the second electroluminescene substrate connecting with the first circuit board and the second circuit board respectively is shown in FIG. 2B. As in FIG. 2B, the first conductive circuit bonding area (not shown) and the second conductive circuit bonding area 221A are disposed on the two corresponding sides of the double-sided electroluminescene display 2 respectively, and connect with the first circuit board 26 and the second circuit board 27 respectively. However, as shown in FIG. 2C, in other embodiments of the present invention, the first conductive circuit bonding area (not shown) and the second conductive circuit bonding area 221A can also be disposed on two adjacent sides of the double-sided electroluminescene display 2 respectively and connect successfully with the first circuit board 26 and the second circuit board 27. In FIG. 2D, only a protective layer 24 is form between first electroluminescene light emitting diodes 212 and second electroluminescene light emitting diodes 222.

In the double-sided electroluminescene display of the present invention, the first electroluminescene substrate and the second electroluminescene substrate may be an organic light emitting diode substrate, and the first circuit board and the second circuit board connecting with the double-sided electroluminescene display to transmit driving signals can be a rigid printed circuit (RPC) board or flexible printed circuit (FPC) board.

The foregoing description is not intended to be exhaustive or to limit the invention to the precise forms disclosed. Obvious modifications or variations are possible in light of the above teachings. In this regard, the embodiment or embodiments discussed were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly and legally entitled.

1. A double-sided electroluminescene display, comprising:
a first electroluminescene substrate having a first conductive circuit bonding area;
a second electroluminescene substrate having a second conductive circuit bonding area; and
a sealant, disposed between said first electroluminescene substrate and said second electroluminescene substrate, for bonding said first electroluminescene substrate with said second electroluminescene substrate so as to form a panel, wherein said first conductive circuit bonding area and said second conductive circuit bonding area are on different sides of said panel.

2. The double-sided electroluminescene display of claim 1, wherein at least one of said first electroluminescene substrate and said second electroluminescene substrate comprises:
a substrate; and
a plurality of electroluminescene light emitting diodes disposed on said substrate.

3. The double-sided electroluminescene display of claim 2, further comprising:
a first protective layer disposed on said electroluminescene light emitting diodes of said first electroluminescene substrate; and
a second protective layer disposed on said electroluminescene light emitting diodes of said second electroluminescene substrate.

4. The double-sided electroluminescene display of claim 1, further comprising a protective layer disposed between said first electroluminescene substrate and said second electroluminescene substrate.

5. The double-sided electroluminescene display of claim 1, further comprising an absorbent disposed between said first electroluminescene substrate and said second electroluminescene substrate.

6. The double-sided electroluminescene display of claim 1, further comprising:
a first circuit board electrically connecting to said first conductive circuit bonding area; and
a second circuit board electrically connecting to said second conductive circuit bonding area.

7. The double-sided electroluminescene display of claim 6, wherein said first circuit board and said second circuit board comprise flexible circuit boards.

8. The double-sided electroluminescene display of claim 6, further comprising a protective layer disposed between said first electroluminescene substrate and said second electroluminescene substrate.

9. The double-sided electroluminescene display of claim 8, wherein said first conductive circuit bonding area and said second conductive circuit bonding area are on two opposite sides of said panel respectively.

10. The double-sided electroluminescene display of claim 8, wherein said first conductive circuit bonding area and said second conductive circuit bonding area are on adjacent sids of said panel respectively.

11. The double-sided electroluminescene display of claim 8, wherein said first electroluminescene substrate and said second electroluminescene substrate are organic light emitting diode substrates.

12. The double-sided electroluminescene display of claim 1, wherein said first electroluminescene substrate and said second electroluminescene comprise organic light emitting diode substrates.

13. The double-sided electroluminescene display of claim 1, wherein said first conductive circuit bonding area and the second conductive circuit bonding area are on opposite sides of said panel, respectively.

14. The double-sided electroluminescene display of claim 1, wherein said first conductive circuit bonding area and said second conductive circuit bonding area are on adjacent sides of said panel, respectively.

15. The double-sided electroluminescene display of claim 1, wherein said sealant is disposed substantially around said first electroluminescene substrate and said second electroluminescene substrate.
